(19) United States
(12) Patent Application Publication
(10) Pub. No.: US 2012/0086019 A1
(43) Pub. Date: Apr. 12, 2012

(54) SUBSTRATE FOR DISPLAY PANEL, AND DISPLAY DEVICE

(75) Inventor: Seiji Kaneko, Osaka (JP)

(73) Assignee: SHARP KABUSHIKI KAISHA, Osaka (JP)

(21) Appl. No.: 13/378,154

(22) PCT Filed: Feb. 18, 2010
(86) PCT No.: PCT/JP10/01036

§ 371 Date: Dec. 14, 2011

(30) Foreign Application Priority Data
Jun. 16, 2009 (JP) 2009-143447

(51) Int. Cl. H01L 33/62

(52) U.S. Cl. 257/82; 257/E33.076

(57) ABSTRACT

Disclosed is a substrate for display panel that includes, in a pixel, a PIN diode 21 that conducts currents of different values based on the amount of light received, a first inorganic insulating film 11 formed over the PIN diode 21, metal electrodes 12c and 12d that are formed over the first inorganic insulating film 11 and that are connected to the PIN diode 21, an organic insulating film 14 formed over the metal electrodes 12c and 12d, a transparent pixel electrode 15 formed on the organic insulating film 14, and a conductive film 13 that is interposed between the organic insulating film 14 and the first inorganic insulating film 11 and that is patterned so as to partially overlap and partially form an opening with respect to an I-layer 8d of the PIN diode 21.

### TECHNICAL FIELD

The present invention relates to a substrate for display panel having a light receiving element (optical sensor) and to a display device having this substrate for display panel.

### BACKGROUND ART

In recent years, display devices in which a plurality of optical sensors are disposed at regular intervals in display regions of the display devices having a plurality of pixels and in which these optical sensors are provided inside the corresponding pixels have been developed. In addition to a conventional display function, these display devices can have other functions, such as a touch panel (area sensor) function that can detect a touched position when a panel surface is touched by an input pen, a person's finger, or the like, for example, using the light intensity detecting function of the optical sensors, and the like.

As optical sensors provided in such display devices, there are PIN photodiodes and the like, for example. The configuration of a PIN photodiode can be divided into two types: a vertical configuration in which a P-layer, an Mayer, and an N-layer are laminated in this order with respect to a substrate; and a horizontal (lateral) configuration in which a P-layer, an Mayer, and an N-layer are arranged in an in-plane direction on a substrate. Here, the P-layer is a semiconductor layer having a high P-type impurity concentration. The Mayer is either an intrinsic semiconductor layer or a semiconductor layer having a low impurity concentration. The N-layer is a semiconductor layer having a high N-type impurity concentration.

Between these, the lateral configuration is a configuration in which the respective layers of the P-layer, the Mayer, and the N-layer do not overlap with one another. Because of this, parasitic capacitances between the respective layers become lower. As a result, the lateral configuration has faster sensing speed than the vertical configuration, which is advantageous. Consequently, the lateral configuration is used often.

Moreover, the lateral configuration can be manufactured in a simple manner using the same process as that of other elements formed on the substrate and the like, which is also advantageous.

For example, Patent Document 1 describes a liquid crystal display device having a configuration in which a PIN photodiode is used as an optical sensor.

The above-mentioned liquid crystal display device is described as follows with reference to FIG. 15.

On an element formation surface 114a of an array substrate 114, a light shielding film 141 for blocking a light L1 from entering a TFT element 150 of a display unit 123 from a backlight and a light shielding film 142 for blocking a light L1 from entering a PIN diode 145 of a light receiving section 124 from the backlight are formed.

Over both of the light shielding films 141 and 142, an insulating film 143 made of a silicon oxide film or the like that is laminated so as to cover substantially all of the surface of the element formation surface 114a is formed.

On the upper surface of the insulating film 143 and above the light shielding film 141, a semiconductor layer 144 (a P-type channel region 144c, an N-type source region 144s, and an N-type drain region 144d) constituting the TFT element 150 is formed.

Furthermore, on the upper surface of the insulating film 143 and above the light shielding film 142, a PIN diode 145 (an I-type region 145i, an N-type region 145n, and a P-type region 145p of polycrystalline semiconductor) that is an optical sensor is formed.

Over the semiconductor layer 144 and the PIN diode 145, a gate insulating film 146 made of a silicon oxide film or the like that is laminated so as to cover substantially all of the surface of the element formation surface 114a is formed. On the upper surface of this gate insulating film 146 and above the channel region 144c of the semiconductor layer 144, a gate electrode 147 is formed.

On this gate electrode 147, a first interlayer insulating film 151 made of a silicon oxide film or the like is formed so as to cover the gate insulating film 146.

On the source region 144s and the drain region 144d of the semiconductor layer 144, contact holes H1 and H2 are respectively formed. Inside the contact hole H1, a data line Ly electrically connected to the source region 144s is formed. Inside the contact hole H2, a drain electrode 152 electrically connected to the drain region 144d is formed.

On the N-type region 145n and the P-type region 145p of the PIN diode 145, contact holes H3 and H4 are respectively formed. Inside the contact hole H3, a first electrode 153 electrically connected to the N-type region 145n is formed. Inside the contact hole H4, a second electrode 154 electrically connected to the P-type region 145p is formed.

On the data line Ly, the drain electrode 152, and the first and second electrodes 153 and 154, a second interlayer insulating film 155 made of a silicon oxide film or the like is formed so as to cover the first interlayer insulating film 151. On the second interlayer insulating film 155, an organic planarization film 156 made of an acrylic resin or the like is formed.

On the drain electrode 152, a via hole 158 is formed. Inside this via hole 158 and on a cholesteric liquid crystal layer 157, which is located above the region where the PIN diode 145 is formed, a pixel electrode 159 made of a light transmissive conductive material such as ITO or the like is formed for each pixel. Here, the pixel electrode 159 is connected to the drain electrode 152 through the via hole 158.

The array substrate 114 and a color filter substrate 115, which is provided with filter layers 133 of the respective colors (only a red color filter layer 133R is shown in the figure), are disposed such that the pixel electrode 159 and an opposite electrode 161 face each other. Between the pixel electrode 159 and the opposite electrode 161, a nematic liquid crystal 117 is encapsulated.

In the above-mentioned configuration, capacitance values of parasitic capacitances can be lowered by disposing the organic planarization film 156 that has a relatively low permittivity between the pixel electrode 159 and the respective signal lines such as the data line Ly and the like.

Furthermore, the pixel electrode 159 and the respective signal lines can be overlapped, and only light of a specific wavelength (red light Lr) can be reflected by the cholesteric liquid crystal layer 157 disposed above the formation region of the PIN diode 145. As a result, a liquid crystal display device in which the aperture ratio and the light use efficiency are improved can be achieved.

Patent Document 2 indicates that a polarization caused by moisture inside the liquid crystal or moisture entering from a gap of a sealing adhesive agent can be suppressed by lowering the relative permittivity of a planarization film formed on a TFT element. Particularly, Patent Document 2 indicates that the polarization can be made less likely to occur by using a material having the relative permittivity of 5 or lower, or more preferably, 4 or lower.

Patent Document 3 describes a configuration that can prevent a separation formed between an organic film and an inorganic film by including an inorganic insulating film in which a surface in contact with an organic protective film and a surface not in contact with the organic protective film are formed to have different shapes (the surface in contact with the organic protective film has a recessed and projected shape, for example).

### RELATED ART DOCUMENTS

### Patent Documents

Patent Document 1: Japanese Patent Application Laid-Open Publication, “Japanese Patent Application Laid-Open Publication No. 2008-158272 (Published on Jul. 10, 2008)”
Patent Document 2: Japanese Patent Application Laid-Open Publication, “Japanese Patent Application Laid-Open Publication No. H11-274510 (Published on Oct. 8, 1999)”
Patent Document 3: Japanese Patent Application Laid-Open Publication, “Japanese Patent Application Laid-Open Publication No. 2007-116164 (Published on May 10, 2007)”

### SUMMARY OF THE INVENTION

### Problems to be Solved by the Invention

However, the inventor of the present invention noticed that in the configuration of Patent Document 1, when the PIN diode 145, which is an optical sensor formed over the array substrate 114, was operated for a long time, its photocurrent characteristics degraded and that reliability was adversely affected.

It can be considered that this is because electric charges are stored in the organic planarization film 156 due to a voltage applied to the pixel electrode 159, resulting in these electric charges affecting the PIN diode 145 through a capacitance coupling.

The organic insulating film (organic planarization film) having the relative permittivity of 4 or lower described in Patent Document 2 has already been commonly used. Even when such an organic insulating film (organic planarization film) is used, it is difficult to solve the above-mentioned problem of reliability.

Even if a separation between an organic film and an inorganic film can be prevented using the configuration described in Patent Document 3, it is difficult to solve the above-mentioned problem of reliability.

The present invention seeks to address the above-mentioned problems, and has an object of providing a substrate for display panel that can suppress degradation of photocurrent characteristics and that is equipped with a light receiving element (optical sensor) having improved reliability even in a configuration that uses an organic insulating film (organic planarization film) and a display device that is provided with the above-mentioned substrate for display panel.

### Means for Solving the Problems

In order to solve the above-mentioned problems, a substrate for display panel according to the present invention is a substrate for display panel having a plurality of pixels, including, in a pixel: a light receiving element that conducts currents of different values based on an amount of light received; a first inorganic insulating film formed over the light receiving element; a wiring that is formed on the first inorganic insulating film and that is electrically connected to the light receiving element; an organic insulating film formed over the wiring; a transparent pixel electrode formed on the organic insulating film; and a conductive film that is interposed between the organic insulating film and the first inorganic insulating film and that is patterned so as to partially overlap and partially form an opening with respect to a light receiving section of the light receiving element.

According to the above-mentioned configuration, capacitance values of parasitic capacitances formed between the wiring and the transparent pixel electrode can be lowered because the organic insulating film is interposed between the wiring and the transparent pixel electrode.

However, as described above, in this configuration, electric charges are stored in the organic insulating film because of the voltage applied to the transparent pixel electrode. As a result, a defect that these electric charges degrade the photocurrent characteristics of the light receiving element through the capacitance coupling occurs.

Thus, in the above-mentioned configuration, a conductive film for applying a prescribed voltage is interposed between the organic insulating film and the light receiving element, more specifically, between the organic insulating film and the first inorganic insulating film, and is patterned so as to partially overlap and partially form an opening with respect to the light receiving section of the light receiving element. Because of this, even when electric charges are stored in the organic insulating film, effects that these electric charges have on the light receiving section of the light receiving element due to the capacitance coupling can be suppressed.

Thus, even when a configuration using an organic insulating film is used and the light receiving element is driven for a long time, a substrate for display panel equipped with a light receiving element that can suppress degradation of the photocurrent characteristics of the light receiving element and that has improved reliability can be realized.

The conductive film disposed above the light receiving section of the light receiving element can guide light towards the light receiving element side because it partially forms an opening.

Here, the organic insulating film indicates an insulating film made mainly of an organic material, such as an insulating film made exclusively of an organic material or an insulating film containing an added inorganic material as needed.

### Effects of the Invention

As described above, a substrate for display panel of the present invention has a configuration provided with, in a pixel, a light receiving element that conducts currents of different values based on an amount of light received, an inorganic insulating film formed over the light receiving element, a wiring that is formed on the inorganic insulating film and that is connected to the light receiving element, an organic insulating film formed over the wiring, a transparent pixel electrode formed on the organic insulating film, and a conductive film that is interposed between the organic insulating film and the inorganic insulating film and that is patterned so as to partially overlap and partially form an opening with respect to a light receiving section of the light receiving element.

In another aspect, as described above, a substrate for display panel of the present invention has a configuration provided with a light receiving element that conducts currents of different values based on an amount of light received, an organic insulating film formed on a light entrance path with respect to the light receiving element, and a conductive film that is formed on the entrance path so as to be interposed on a side closer to the light receiving element than the organic insulating film and that is patterned so as to partially overlap and partially form an opening with respect to a light receiving section of the light receiving element.

As described above, a display device according to the present invention has a configuration that is provided with the above-mentioned substrate for display panel.

Thus, the present invention has effects that even in a configuration using an organic insulating film (organic planarization film), a substrate for display panel equipped with a light receiving element (optical sensor) that can suppress degradation of the photocurrent characteristics and that has improved reliability can be achieved.

Furthermore, the present invention has effects that a highly reliable display device that has a bright display quality and that has a touch panel (area sensor) function can be achieved.

### BRIEF DESCRIPTION OF THE DRAWINGS

FIG. 1 is a cross-sectional view showing a schematic configuration of a liquid crystal display device equipped with a substrate for display panel according to Embodiment 1 of the present invention.

FIG. 2(a) is a plan view of a PIN diode provided in the substrate for display panel of FIG. 1 viewed from a metal wiring network formation surface side. FIG. 2(b) to FIG. 2(f) are plan views showing modification examples of the PIN diode.

FIG. 3(a) is a cross-sectional view along the line A-A′ in FIG. 2(a). FIG. 3(b) is a cross-sectional view corresponding to FIG. 3(a) in a comparative example.

FIG. 4(a) is a chart showing the usage environment temperature dependence of leakage currents in an organic insulating film. FIG. 4(b) is a chart showing the usage environment temperature dependence of leakage currents in an inorganic insulating film.

FIG. 5 is a graph showing changes in the photocurrent characteristics over time of a PIN diode that is equipped in a substrate for display panel shown in FIG. 3(b), which is a comparative example.

FIG. 6 is a graph showing changes in the photocurrent characteristics over time of a PIN diode that is equipped in a substrate for display panel of Embodiment 1 shown in FIG. 3(a).

FIG. 7 is a drawing showing measurement conditions for measuring the voltage dependence of photocurrents in a PIN diode.

FIG. 8 is a graph showing the voltage dependence of photocurrents in a PIN diode.

FIG. 9 is a circuit diagram showing one example of a circuit configuration of a single pixel unit constituted of the respective pixels of red, green, and blue in the substrate for display panel of FIG. 1.

FIG. 10 is a circuit diagram showing another example of a circuit configuration of a single pixel unit constituted of the respective pixels of red, green, and blue in the substrate for display panel of FIG. 1.

FIG. 11 is a drawing showing an example of the circuit configuration shown in FIG. 10 in which a metal wiring network bus line is led out in an extending direction of a reset signal line and a row selection signal line.

FIG. 12 is a drawing showing an example of the circuit configuration shown in FIG. 10 in which a metal wiring network bus line is led out in an extending direction of a source signal line (power supply line) and a source signal line (output signal line).

FIG. 13 is a plan view of a PIN diode equipped in a substrate for display panel according to Embodiment 2 of the present invention as viewed from a metal wiring network formation surface side.

FIG. 14 is a cross-sectional view along the line B-B′ in FIG. 13.

FIG. 15 is a cross-sectional view of main parts showing a display unit and a light receiving section in a pixel in a conventional liquid crystal display device.

### DETAILED DESCRIPTION OF EMBODIMENTS

Embodiments of the present invention are described in detail below with reference to figures. However, the dimensions, materials, and shapes of components described in these embodiments, as well as their relative positions are merely examples. The scope of the invention should not be limited by them.

### Embodiment 1

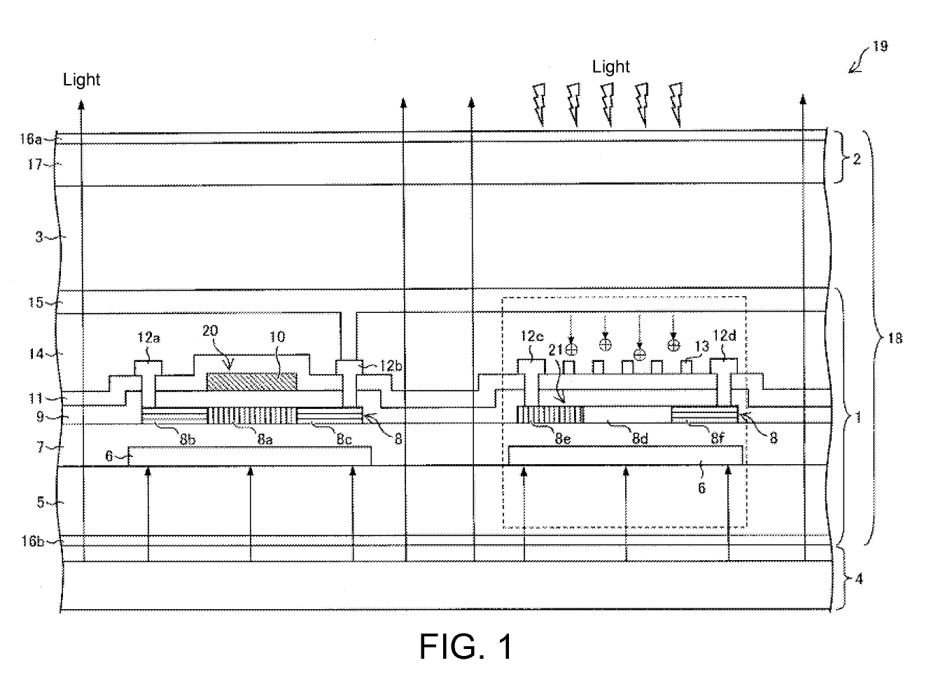

A configuration of an active matrix substrate 1, which is a substrate for display panel according to the present invention, and a configuration of a liquid crystal display device 19, which is a display device according to the present invention, are described below with reference to FIG. 1 to 12.

Here, a display device of the present invention is not limited to the liquid crystal display device 19, and can be embodied as an organic EL display device or the like, for example.

As shown in FIG. 1, the liquid crystal display device 19 includes the active matrix substrate 1 and a color filter substrate 2 that is disposed to face the active matrix substrate 1, and includes a liquid crystal display panel 18 having a configuration in which a liquid crystal layer 3 is encapsulated between these substrates 1 and 2 by a sealing material.

In addition, the liquid crystal display device 19 has a backlight unit 4 that emits light towards the liquid crystal display panel 18.

On a glass substrate 17 of the color filter substrate 2, a color filter layer, a common electrode, an alignment film, and the like, which are not shown in the figure, are formed. On the side opposite from the color filter layer formation surface, a polarizing plate 16a is provided.

Also, a polarizing plate 16b is provided on the surface of the active matrix substrate 1 facing the backlight unit 4.

A configuration of the active matrix substrate 1 is described in detail below.

The active matrix substrate 1 has a display region constituted of a number of transparent pixel electrodes 15 arranged in a matrix.

As shown in FIG. 1, in a region where the respective transparent pixel electrode 15 is formed, a pixel TFT 20, which is an active element for controlling the transparent pixel electrode 15, and a PIN diode 21, which is a light receiving element for achieving a touch panel function, are provided.

In the above-mentioned configuration, a voltage for displaying a desired image can be applied to the transparent pixel electrode 15 by the pixel TFT 20, and a touch by a finger, a pen, or the like, for example, can be detected by the PIN diode 21, which conducts currents of different values based on the amount of light received.

As described above, in the liquid crystal display device 19 having a touch panel (area sensor) function equipped with the active matrix substrate 1, which has the pixel TFT 20 and the PIN diode 21 formed on the same substrate, the thickness and the manufacturing costs can be reduced compared to a liquid crystal display device having a touch panel that uses a resistive film method or a capacitance method.

That is, the active matrix substrate 1 is provided with a plurality of transparent pixel electrodes 15, the pixel TFTs 20 connected to the respective transparent pixel electrodes 15, and a plurality of PIN diodes 21, which conducts currents of different values based on the amount of light received.

Here, the pixel TFTs 20 are provided in the respective pixels formed of the respective transparent pixel electrodes 15. However, the PIN diode 21 is not necessarily required to be provided in all of the pixels, and may be provided only in the necessary pixels, taking into account the resolution needed to detect a touched position.

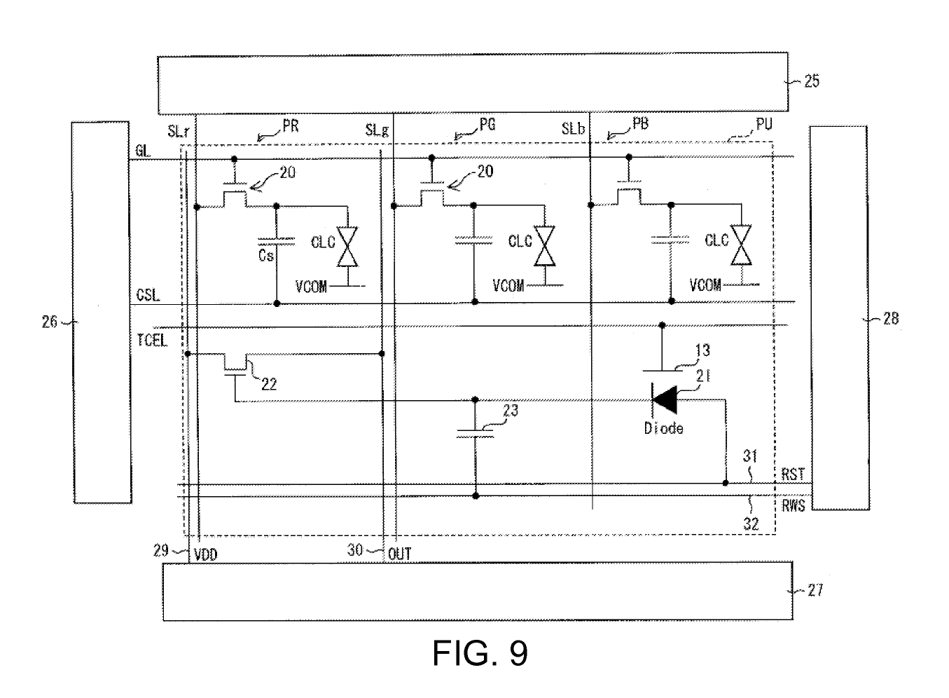

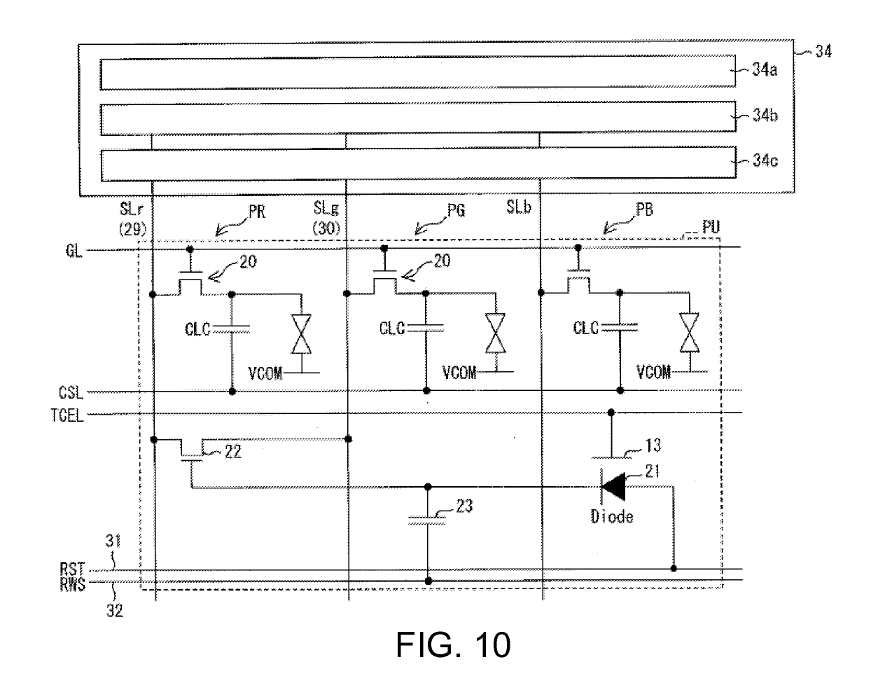

The liquid crystal display device 19 is constituted of pixels of red, green, and blue, and in the present embodiment, the PIN diodes 21 are provided only in the pixels corresponding to blue. Transistors and capacitances connected to the PIN diodes 21 are provided in pixels corresponding to red or green (see FIGS. 9 and 10, which are described later). However, the present invention is not limited thereto.

Here, in the present embodiment, the PIN diodes 21 having a configuration in which the respective layers of a P-layer 8e, an Mayer 8d, and N-layer 8f shown in FIG. 1 do not overlap one another are used from the standpoint of manufacturing the active matrix substrate 1 provided with a light receiving element that has a fast sensing speed as an optical sensor in a relatively simple manner. However, the present invention is not limited thereto.

Thus, as the light receiving element, any light receiving element that conducts currents of different values based on the amount of light received by a light receiving section provided in the light receiving element can be used. A CCD, a CMOS, a PN diode, a phototransistor, or the like can be used, for example.

A process of forming the pixel TFT 20 and the PIN diode 21 in the active matrix substrate 1 at the same time is described below. A configuration of the active matrix substrate 1 is also described in detail.

In the present embodiment, a glass substrate 5 is used as a substrate to form the active matrix substrate 1. However, other than the glass substrate 5, a quartz substrate, a plastic substrate, or the like can be used as the substrate to form the active matrix substrate 1.

On the surface of the glass substrate 5 on which the pixel TFT 20 and the PIN diode 21 are to be formed, light shielding films 6 and 6 for blocking light emitted from the backlight unit 4 from entering the pixel TFT 20 and the PIN diode 21 are respectively formed.

Above the respective light shielding films 6 and 6, a base coat film 7 is formed so as to cover the respective light shielding films 6 and 6, as well as the glass substrate 5.

For the base coat film 7, a film made of an insulating inorganic material, such as a silicon oxide film, a silicon nitride film, a silicon nitride oxide film, or the like, or a multilayer film that is formed by appropriately combining these films can be used. In the present embodiment, a silicon oxide film was used. These films can be formed by depositing a film using a LPCVD method, a plasma CVD method, a sputtering method, or the like.

Here, the base coat film 7 also functions as a film for preventing impurity diffusion from the glass substrate 5 and preventing damage to the glass substrate 5 caused by heat generated during laser irradiation.

The pixel TFT 20 and the PIN diode 21 are respectively formed in regions of the upper surface of the base coat film 7 that are located above the respective light shielding films 6 and 6.

Thus, as shown in FIG. 1, the base coat film 7 becomes an interlayer film between the above-mentioned light shielding films 6 and 6 and the pixel TFT 20 as well as the PIN diode 21.

The process of forming the pixel TFT 20 and the PIN diode 21 is as follows.

First, in regions on the base coat film 7 that are above the respective light shielding films 6 and 6, a non-single crystalline semiconductor thin film that will become polycrystalline semiconductor films 8 later is respectively formed using an LPCVD method, a plasma CVD method, a sputtering method, or the like.

Here, as the above-mentioned non-single crystalline semiconductor thin film, amorphous silicon, polycrystalline silicon, amorphous germanium, polycrystalline germanium, amorphous silicon-germanium, polycrystalline silicon-germanium, amorphous silicon carbide, polycrystalline silicon carbide, or the like can be used. In the present embodiment, amorphous silicon was used.

Next, the above-mentioned non-single crystalline semiconductor thin film is crystallized to form polycrystalline semiconductor film 8. For crystallization, a laser beam, an electron beam, or the like can be used. In the present embodiment, crystallization was performed using a laser beam.

Next, the polycrystalline semiconductor film 8 is patterned corresponding to the formation regions of the light shielding films 6 using a photolithography method.

Then, a P-type channel region 8a is formed in the middle of the polycrystalline semiconductor film 8 in the region where the pixel TFT 20 is formed. On the sides of the channel region 8a, an N-type source region 8b and an N-type drain region 8c are respectively formed.

On the other hand, an Mayer 8d, which is either an intrinsic semiconductor layer or a semiconductor layer having a relatively low impurity concentration, is formed in the middle of the polycrystalline semiconductor film 8 in the region where the PIN diode 21 is formed. On the sides of the Mayer 8d, a P-layer 8e, which is a semiconductor layer having a relatively high P-type impurity concentration, and an N-layer 8f, which is a semiconductor layer having a relatively high N-type impurity concentration, are respectively formed.

Next, on the entire upper surface of the glass substrate 5, a gate insulating film 9 that is made of a deposited silicon oxide film or the like is formed. The gate insulating film 9 covers the polycrystalline semiconductor films 8.

In the present embodiment, the gate insulating film 9 also covers the polycrystalline semiconductor film 8 in the region where the PIN diode 21 is formed. However, the gate insulating film 9 may cover only the polycrystalline semiconductor film 8 in the region where the pixel TFT 20 is formed.

Then, over the gate insulating film 9, a TaN film and a W film are laminated as a conductive film, for example. Here, in the present embodiment, a film obtained by laminating a TaN film and a W film is used as the above-mentioned conductive film. However, it is not limited thereto, and the conductive film may be formed of an element selected from Ta, W, Ti, Mo, Al, Cu, Cr, Nd, or the like, an alloy material having the element mentioned above as a main component, or a compound material thereof. Alternatively, the conductive film may be formed of a semiconductor film, which is represented by polycrystalline silicon or the like, doped with an impurity such as phosphorus, boron, or the like.

Then, the conducive film is patterned by etching using a resist pattern (not shown in the figure) that is formed by a photolithography method to form a gate electrode 10.

Next, a first inorganic insulating film 11 made of a deposited silicon oxide film or the like is formed so as to cover the upper surface of the gate electrode 10 and the upper surface of the gate insulating film 9 in regions where the gate electrode 10 is not formed.

Then, contact holes that run through the gate insulating film 9 and the first inorganic insulating film 11 are formed above the N-type source region 8b, the N-type drain region 8c, the P-layer 8e, and the N-layer 8f, respectively.

Then, a conductive film is formed over the entire upper surface of the glass substrate 5 by a sputtering method or the like.

As the conductive film, a conductive film made of aluminum or the like can be used, for example. However, it is not limited thereto, and an element selected from Ta, W, Ti, Mo, Al, Cu, Cr, Nd, or the like, an alloy material having the element mentioned above as a main component, or a compound material thereof may be used. Alternatively, a multilayer configuration may be formed by appropriately combining these materials as needed. In the present embodiment, aluminum was used.

Here, the conductive film is patterned into a desired shape by etching using a resist pattern (not shown in the figure) formed by a photolithography method as a mask to form a source electrode 12a and a drain electrode 12b, which are electrically connected to the N-type source region 8b and the N-type drain region 8c of the pixel TFT 20, respectively.

Similarly, the above-mentioned conductive film also becomes metal electrodes (wiring lines) 12c and 12d electrically connected to the P-layer 8e and the N-layer 8f of the PIN diode 21, respectively.

Similarly, the above-mentioned conductive film also becomes a metal wiring network 13 formed above the Mayer 8d of the PIN diode 21. The metal wiring network 13 is described later.

Next, a transparent organic insulating film 14 is formed by spin coating or slit coating so as to cover the first inorganic insulating film 11, the source electrode 12a, the drain electrode 12b, the metal electrodes 12c and 12d, and the metal wiring network 13.

Then, on the drain electrode 12b, a via hole that runs through the transparent organic insulating film 14 is formed. If the transparent organic insulating film 14 is photosensitive, the via hole can be formed by an exposure and development process. If the transparent organic insulating film 14 is not photosensitive, the via hole can be formed by a dry etching method, for example.

In the present embodiment, an acrylic insulating film was used as the transparent organic insulating film 14.

By using an organic insulating film instead of an inorganic insulating film, the film can be thickened without forming a crack or the like in a simple manner using the above-mentioned coating method or the like. Furthermore, parasitic capacitances formed between wiring lines and electrodes, for example, can be suppressed because the organic insulating film generally has a lower permittivity than the inorganic insulating film.

Furthermore, the organic insulating film can planarize steps in the underling films in a simple manner because it can be thickened in a simple manner.

An inorganic material such as siloxane polymer or the like may be included in the organic insulating film if the film can be thickened without forming a crack or the like.

Lastly, a transparent conductive film, such as ITO, IZO, or the like, is formed by a sputtering method or the like on the transparent organic insulating film 14. The transparent conductive film is patterned into a desired pattern using a photoresist to form the transparent pixel electrode 15.

Here, as shown in the figure, the transparent pixel electrode 15 is electrically connected to the drain electrode 12b.

Although not shown in the figure, an alignment film is formed on the transparent pixel electrode 15.

In the active matrix substrate 1, the source electrode 12a, the drain electrode 12b, the metal electrodes 12c and 12d, and the metal wiring network 13 preferably are formed of the same material. This is because, in this configuration, the metal wiring network 13 can be formed at the same time as the source electrode 12a, the drain electrode 12b, and the metal electrodes 12c and 12d by patterning the same layer as described above, thereby preventing an increase in the manufacturing steps.

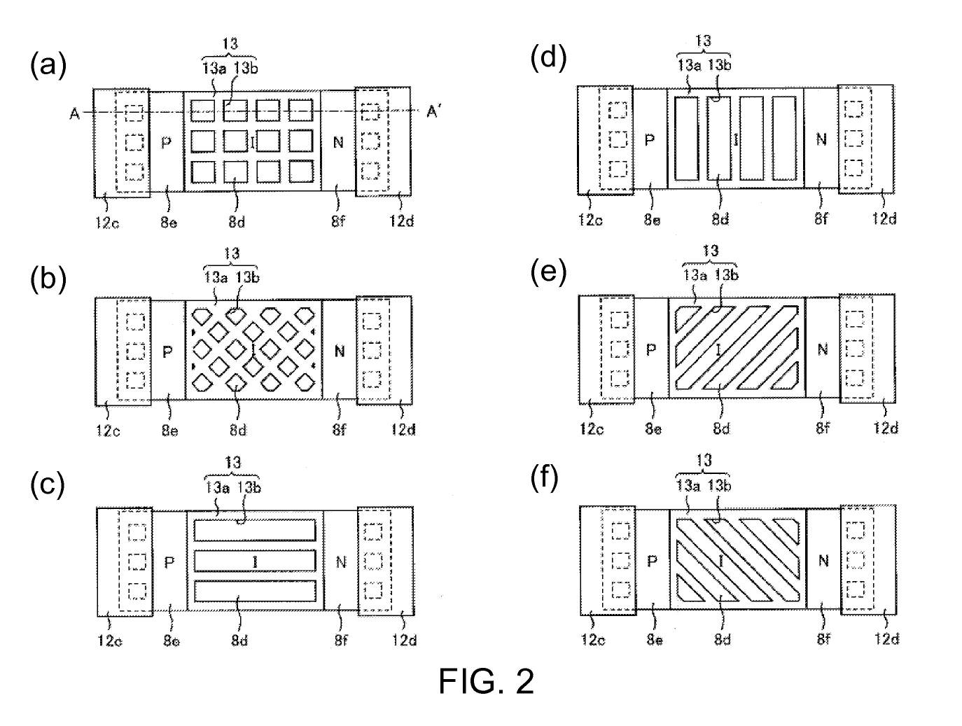

FIG. 2(a) is a plan view of the PIN diode 21 of FIG. 1 viewed from the metal wiring network 13 formation surface side.

The metal wiring network 13 is formed mostly above the Mayer 8d of the PIN diode 21. As shown in FIG. 2(a), it has a planar shape that is patterned to form a grid pattern. Thus, it can be said that the metal wiring network 13 is patterned so as to have an overlapping portion 13a, which overlaps the Mayer 8d, and openings 13b, which are open with respect to the Mayer 8d. The metal wiring network 13 is a member that is formed by patterning a conductive film as described above. Therefore, it has conductivity.

The metal wiring network 13 transmits light entering from the transparent pixel electrode 15 side to the PIN diode 21 side through the openings 13b (light guiding function). This way, the optical detection function in the PIN diode 21 can be retained.

Furthermore, the metal wiring network 13 can suppress the effects to the I-layer 8d of the PIN diode 21 attributed to a capacitance coupling of electric charges formed in the transparent organic insulating film 14 using the overlapping portion 13a, which has conductivity (electric charge effect suppressing function).

Using these functions of the metal wiring network 13, a more reliable active matrix substrate 1 equipped with the PIN diode 21 can be achieved.

The planar shape of the metal wiring network 13 is not limited to the shape shown in FIG. 2(a), and a shape that is patterned so as to partially overlap and partially form an opening with respect to the I-layer 8d, such as a grid pattern shown in FIG. 2(b), slit patterns shown in FIGS. 2(c) to 2(f), or the like, for example, works. However, by making the planar shape of the metal wiring network 13 a grid pattern, the overlapping portion 13a and the openings 13b are arranged to spread out. As a result, the light guiding function and the electric charge effect suppressing function can be realized more evenly with respect to the entire area of the light receiving section of the PIN diode 21. Thus, it can be said that the grid pattern is one of the suitable shapes.

The shapes, areas, arrangements, and the like of the overlapping portion 13a and the openings 13b can be optimized taking into account the light guiding function and the electric charge effect suppressing function.

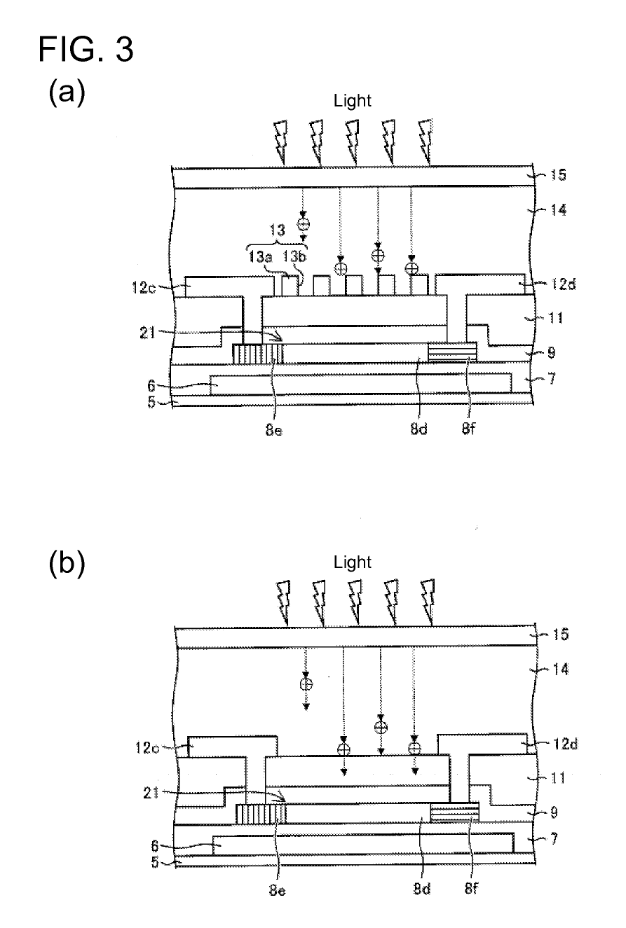

Influences of electric charges accumulated in the transparent organic insulating film 14 upon the I-layer 8d of the PIN diode 21 are described below with reference to FIG. 3.

FIG. 3(a) is a cross-sectional view along the line A-A′ of FIG. 2(a), and shows a schematic configuration of a region where the PIN diode 21 is formed in the active matrix substrate 1 according to the present embodiment.

On the other hand, FIG. 3(b) shows a configuration of the above-mentioned FIG. 3(a) from which the metal wiring network 13 is removed as a comparative example.

The transparent organic insulating film 14 is not as dense compared to an inorganic insulating film formed by the various CVD methods mentioned above.

A prescribed voltage for displaying an image is applied to the transparent pixel electrode 15 formed over the transparent organic insulating film 14. As a result, electric charges are stored in the transparent organic insulating film 14, and these electric charges affect the I-layer 8d of the PIN diode 21 through a capacitance coupling.

In order to suppress such influence, in the active matrix substrate 1 of the present embodiment, the metal wiring network 13 is disposed between the first inorganic insulating film 11 and the transparent organic insulating film 14 so as to cover the I-layer 8d of the PIN diode 21 as shown in FIG. 3(a).

Here, the metal wiring network 13 has the openings 13b. The influence of the electric charges formed above the openings 13b can be also sufficiently suppressed by the overlapping portions 13a adjacent to the openings 13b.

In contrast, in the comparative example of FIG. 3(b), the metal wiring network 13 is not provided, and the influences mentioned above cannot be suppressed.

Generally, in an organic insulating film such as the transparent organic insulating film 14 or the like, there is a possibility that the insulating property is not retained and that slight leakage currents are formed depending on its usage environment.

For example, as the temperature of the usage environment of the above-mentioned organic insulating film increases, the leakage currents tend to increase.

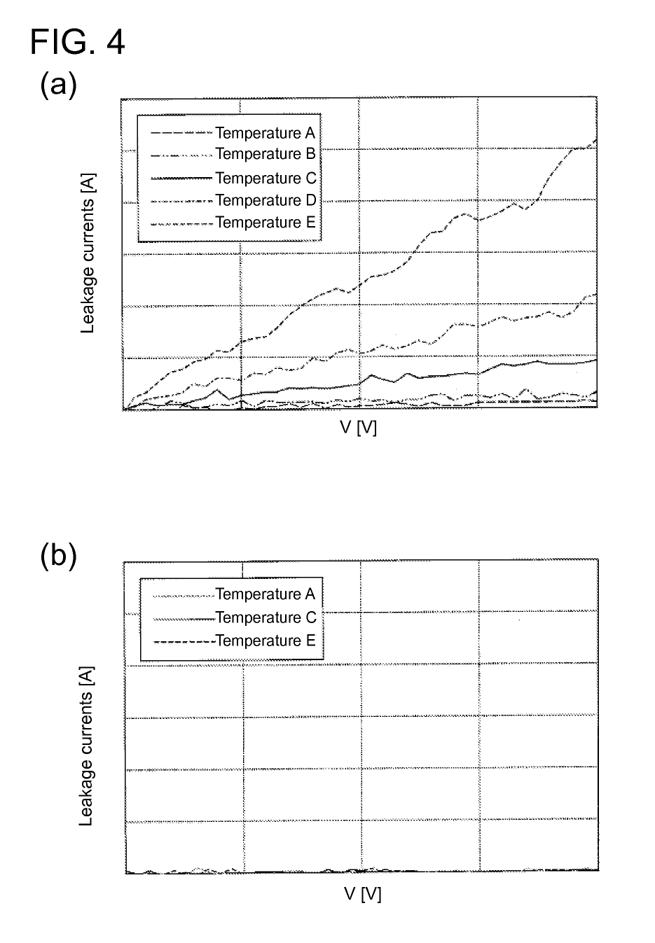

FIG. 4(a) shows the usage environment temperature dependence of leakage currents in the above-mentioned organic insulating film. FIG. 4(b) shows the usage environment temperature dependence of leakage currents in an inorganic insulating film.

As shown in FIG. 4(a), in the above-mentioned organic insulating film, as the usage environment temperature rises from A to E, its leakage currents also increase. In contrast, as shown in FIG. 4(b), in the inorganic insulating film, its leakage currents do not increase and remain substantially the same even when the usage environment temperature rises from A to E.

In the transparent organic insulating film 14 used in the present embodiment, its leakage currents also tend to increase as the usage environment temperature rises. Consequently, due to a difference in potential between the transparent pixel electrode 15 and the metal electrodes 12c and 12d, as well as the I-layer 8d, electric charges move into the transparent organic insulating film 14, causing the electric charges to be stored in the transparent organic insulating film 14.

The electric charges stored in the transparent organic insulating film 14 as described above adversely affect the photocurrent characteristics of the PIN diode 21 by the mechanism described below.

When a prescribed voltage is applied to the PIN diode 21, a depletion layer region is formed in a semiconductor layer disposed in the PIN diode 21. When this depletion layer region is irradiated with light, photocurrents flow into the PIN diode 21 by a photoelectric effect.

However, when electric charges are stored in the transparent organic insulating film 14, a desired depletion layer region cannot be obtained even when a prescribed voltage is applied to the PIN diode 21 due to a capacitance coupling of these stored electric charges. As a result, a prescribed amount of photocurrent cannot be obtained.

In contrast, in the present embodiment, the adverse effects described above can be suppressed by providing the metal wiring network 13 and applying a prescribed voltage to the metal wiring network 13.

According to the above-mentioned configuration, electric charge transfer inside the transparent organic insulating film 14 can be suppressed.

The metal wiring network 13 is disposed in a location closer to the PIN diode 21 than the location where the electric charges are present. Therefore, in this configuration, the PIN diode 21 is not affected by the stored electric charges and is affected only by the voltage applied to the metal wiring network 13 (the voltage that can obtain the optimal characteristics of the PIN diode 21, which is described later in detail).

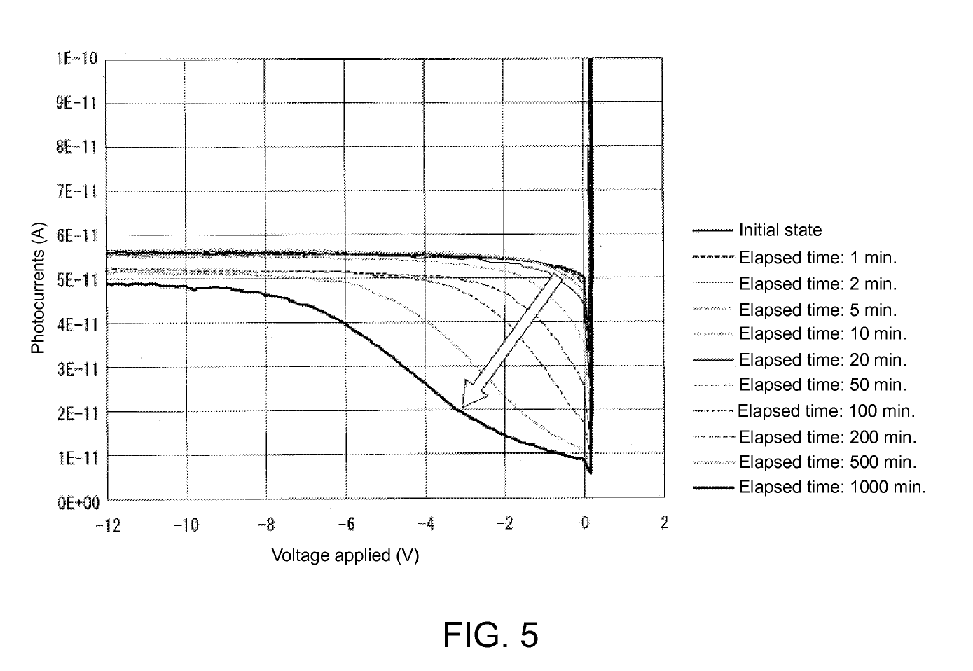

FIG. 5 shows changes in photocurrent characteristics over time when an operation voltage is applied to the PIN diode in the comparative example shown in FIG. 3(b).

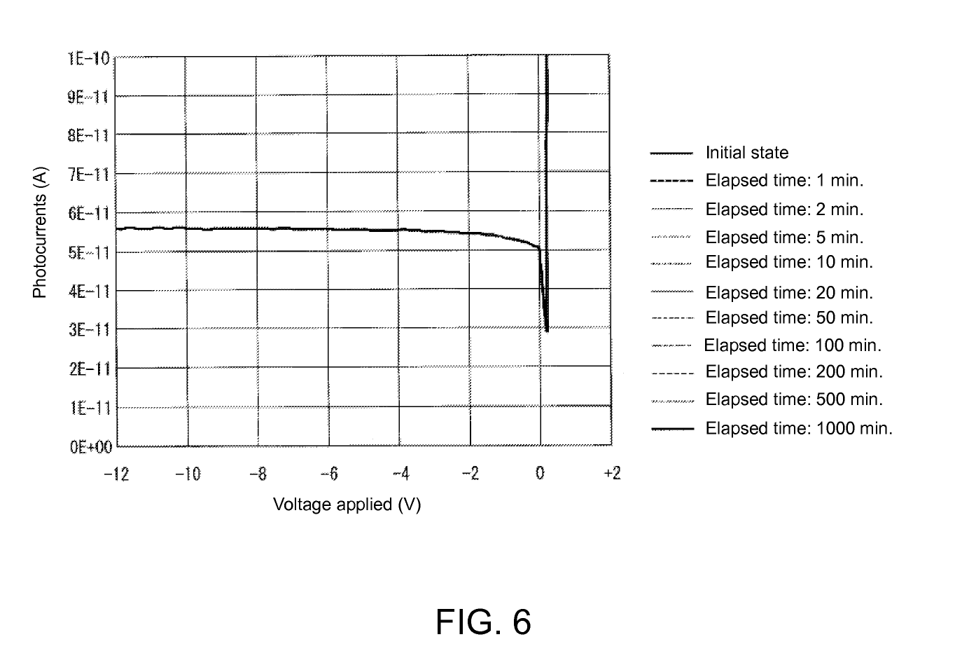

FIG. 6 shows changes in photocurrent characteristics over time when an operation voltage is applied to the PIN diode 21 provided in the active matrix substrate 1 of the present embodiment shown in FIG. 3(a). However, to facilitate the experiment, FIG. 6 shows the results obtained using a configuration in which a transparent conductive member that does not have openings 13b is disposed instead of the metal wiring network 13 of FIG. 3(a). The configuration that uses the metal wiring network 13 and the configuration that uses the above-mentioned transparent conductive member have different aperture ratios. Therefore, it cannot be said that they have exactly the same photocurrent characteristics. However, it can be understood that they show the same tendency in terms of the changes in photocurrent characteristics over time.

FIGS. 5 and 6 respectively show the results of changes in photodiode characteristics (changes in photocurrents with respect to the changes in voltage applied) over time (initial state, and from 1 minute to 1000 minutes of irradiation time) measured while the respective PIN diodes 21 mentioned above were irradiated with light of constant intensity. Here, the horizontal axes in FIGS. 5 and 6 show the voltages applied to the PIN diodes 21 (negative (−) means a reverse bias). The vertical axes show photocurrents flowing into the PIN diodes 21 (“1E-10” means 1×10⁻¹⁰).

As shown in FIG. 5, in the comparative example (configuration without the metal wiring network 13), degradation of the characteristics of the PIN diode 21 such as lowering of the photocurrent value occurs over time.

It can be considered that this is caused by electric charges stored in the transparent organic insulating film 14 interposed between the transparent pixel electrode 15 and the first inorganic insulating film 11 as described above.

In contrast, as shown in FIG. 6, in the PIN diode 21 provided in the active matrix substrate 1 of the present embodiment, lowering of the photocurrent value over time does not occur.

This is because, as shown in FIG. 3(a), the metal wiring network 13 is formed between the transparent organic insulating film 14 and the Mayer 8d of the PIN diode 21 so as to cover the Mayer 8d and a desired voltage is applied, thereby suppressing influences of the stored electric charges generated in the transparent organic insulating film 14 upon the PIN diode 21.

Here, as shown in FIG. 6, as for the photocurrent characteristics of the PIN diode 21 when a reverse bias is applied, the photocurrents preferably are as flat as possible with respect to the reverse bias.

In the present embodiment, in order to optimally suppress the influences of the stored electric charges generated in the transparent organic insulating film 14 upon the PIN diode 21, the metal wiring network 13 is formed on the overall surface of the Mayer 8d as shown in FIG. 2(a). However, the above-mentioned suppression effects can be obtained even when the metal wiring network 13 is provided in a part of the Mayer 8d.

Next, conditions of voltages applied to the metal wiring network 13 are described.

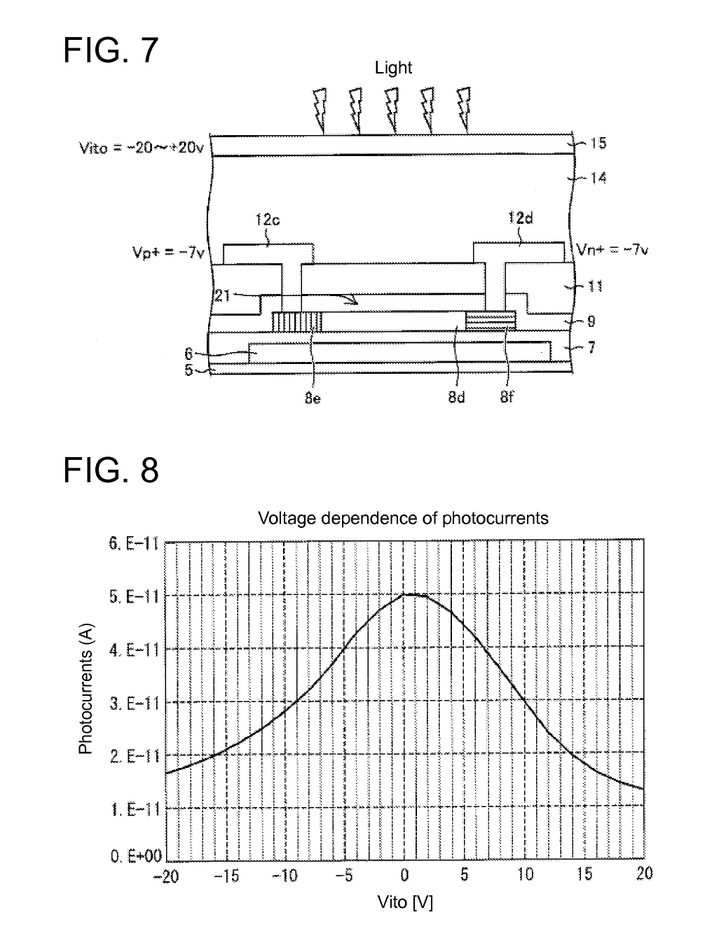

In order to study the conditions of voltages applied to the metal wiring network 13, the voltage dependence of the PIN diode 21 was measured under the conditions shown in FIG. 7. Here, to facilitate measurement, a configuration corresponding to the above-mentioned comparative example was used. In this configuration, −7V was applied to the metal electrode 12c (the anode of the PIN diode 21), and −7V was applied to the metal electrode 12d (the cathode of the PIN diode 21). While a constant amount of light was irradiated onto the PIN diode 21 through the transparent pixel electrode 15, the voltage Vito of the transparent pixel electrode 15 was changed within the range between −20V and +20V.

As a result, the photocurrent flowing through the PIN diode 21 changed as shown in FIG. 8. In order to improve the detecting ability of the PIN diode 21, it is preferable to select a condition at which the higher electric current value is achieved with a constant amount of received light. Thus, based on FIG. 8, it can be said that in these measurement results, Vito can be suitably set at around 0V (between −5V and +7V, for example).

Here, as described above, the configuration used in this measurement corresponds to the above-mentioned comparative example. In the configuration of the present embodiment in which the metal wiring network 13 is added (FIG. 3(a)), the voltage of the metal wiring network 13 can be changed according to the above-mentioned Vito to find the optimal conditions of the voltage set for the metal wiring network 13.

Thus, in the active matrix substrate 1, when the Mayer 8d of the PIN diode 21 shows a certain amount of light received, the voltage applied to the metal wiring network 13 preferably is a voltage that maximizes the value of the electric current flowing through the PIN diode 21.

If the length, the thickness, or the like of the Mayer 8d of the PIN diode 21 changes, for example, the optimal voltage to be applied to the metal wiring network 13, which maximizes the value of the electric current flowing through the PIN diode 21, changes as well.

Thus, when the Mayer 8d of the PIN diode 21 shows a certain amount of light received, the voltage to be applied to the metal wiring network 13 is modified such that the value of the electric current flowing through the PIN diode 21 is maximized to further improve the characteristics of the PIN diode 21.

Next, with reference to FIG. 9 to 10, circuit configurations of the active matrix substrate 1 are described. A specific configuration for applying a voltage to the metal wiring network 13 is also described. FIGS. 9 and 10 respectively show examples of a circuit configuration of a single pixel unit PU constituted of the respective pixels PR, PG, and PB, which are pixels for displaying red, green, and blue, respectively in the active matrix substrate 1 of the present embodiment.

As shown in FIG. 9, on the upper side of the active matrix substrate 1 in the figure, a source driver 25 is disposed. On the left side in the figure, a gate driver 26 is disposed. On the lower side in the figure, a sensor read out driver 27 is disposed, and on the right side in the figure, a sensor row driver 28 is disposed.

In the upper side region of the figure (the region on the side closer to the source driver 25) of the respective pixels PR, PG, and PB, the respective intersections of source signal lines SLr, SLg, and SLb, which are connected to the source driver 25, and a gate signal line GL connected to the gate driver 26 are disposed. In the proximity of these intersections, pixel TFTs 20 are provided. In the lower side region of the figure in the blue pixel PB (the region on the side closer to the sensor read out driver 27), a PIN diode 21 is formed. In the lower side region of the figure in the red pixel PR, a transistor 22 connected to the PIN diode 21 is formed. In the lower side region of the figure in the green pixel PG, a capacitance 23 connected to the PIN diode 21 and the transistor 22 is formed.

By disposing the PIN diode 21, the transistor 22, and the capacitance 23 such that they are spread out in the respective pixels PR, PG, and PB as shown in the configuration above, an increase in the difference of aperture ratios among red, green, and blue can be suppressed.

Here, although omitted in FIG. 1, an auxiliary capacitance Cs parallel to a liquid crystal capacitance CLC is provided in the active matrix substrate 1 in order to extend the decay time of electric charges charged in the liquid crystal capacitance CLC. The auxiliary capacitance Cs is formed between the transparent pixel electrode 15 connected to the drain electrode 12b of the pixel TFT 20 and a common electrode, which faces the transparent pixel electrode 15 and to which the common electrode voltage VCOM is applied.

One end of the auxiliary capacitance Cs is connected to an auxiliary capacitance bus line CSL.

Here, the source of the transistor 22 is connected to a power supply line 29, and the drain is connected to an output signal line 30. The power supply line 29 and the output signal line 30 are connected to the sensor read out driver 27. A power supply voltage VDD is applied to the power supply line 29 from the sensor read out driver 27.

The cathode of the PIN diode 21 (the metal electrode 12d of FIG. 1) is connected to the gate of the transistor 22. One end of the capacitance 23, which is connected to the PIN diode 21, is also connected to the gate of the transistor 22.

Here, the anode of the PIN diode 21 (the metal electrode 12c of FIG. 1) is connected to a reset signal line (reset signal input line) 31 to which a reset signal RST is sent from the sensor row driver 28. The other end of the capacitance 23 is connected to a row selection signal line (selection signal input line) 32 to which a row selection signal RSW is sent. Here, the row selection signal RWS has a role to select a specific row and output a signal from that specific row.

Touch panel operation based on the above-mentioned circuit configuration is described below.

In the above-mentioned configuration, in order to reset the gate potential of the transistor 22, a high level reset signal RST is sent to the reset signal line 31 from the sensor row driver 28. This way, a forward direction bias is applied to the PIN diode 21. As a result, the capacitance 23 becomes charged, and the gate potential rises gradually, finally reaching the reset potential.

After the gate potential reaches the reset potential, the cathode potential of the PIN diode 21 becomes higher than the anode potential when the reset signal RST is dropped to a low level. As a result, a reverse bias is applied to the PIN diode 21. The gate potential at this time is the value obtained by subtracting the amount of drop in forward direction voltage in the PIN diode 21 and the amount of drop in voltage caused by parasitic capacitances of the PIN diode 21 from the above-mentioned reset potential.

If the PIN diode 21 is irradiated with light during this state, photocurrent caused by the reverse bias flows through the PIN diode 21 based on the intensity of light. As a result, electric charges stored in the capacitance 23 are discharged through the reset signal line 31. Thus, the gate potential gradually drops, and eventually drops to a detection potential corresponding to the intensity of light.

Then, in order to read out the results of optical detection, a high level row selection signal RWS is applied to the other end of the capacitance 23 from the sensor row driver 28 through the row selection signal line 32. This way, the gate potential is driven up through the capacitance 23. As a result, the gate potential becomes a potential obtained by adding the high level potential of the row selection signal RWS to the above-mentioned detection potential.

When the gate potential is driven up, the threshold voltage, which turns on the transistor 22, is surpassed, and the transistor 22 becomes turned on. As a result, the voltage controlled by an amplification factor corresponding to the level of the gate potential, i.e., corresponding to the intensity of light, is outputted from the transistor 22 as a detection signal, and is sent to the sensor read out driver 27 through the output signal line 30.

Furthermore, in the circuit configuration shown in FIG. 9, a metal wiring network bus line TCEL is provided separately. This metal wiring network bus line TCEL is for applying a prescribed voltage to the above-mentioned metal wiring network 13, and is led out up to the peripheral region (region outside the display region) of the active matrix substrate 1 for supplying the voltage. To a single metal wiring network bus line TCEL, metal wiring networks 13, which are respectively provided in a number of pixel units PU arranged in a row direction (horizontal direction in FIG. 9) or a column direction (vertical direction in FIG. 9), for example, can be connected.

Because only an optimal voltage (fixed voltage) set as described above can be supplied to the metal wiring network bus line TCEL, the metal wiring network bus line TCEL may be connected to the sensor row driver 28 or the like, for example, so that the optimal voltage can be applied thereto. Alternatively, a separate power supply circuit for applying a voltage to the metal wiring network bus line TCEL may be provided.

Specific wiring examples of the metal wiring network bus line TCEL are described later.

FIG. 10 is a drawing showing an example of a further preferable circuit configuration of a single pixel unit PU constituted of the respective pixels PR, PG, and PB, which are pixels for displaying red, green, and blue, respectively, in the active matrix substrate 1 of the present embodiment.

As shown in FIG. 10, in order to prevent a reduction in the aperture ratio caused by the increased number of wiring lines, this circuit configuration is a configuration in which the source signal line SLr and the power supply line 29, as well as the source signal line SLg and the output signal line 30 are respectively combined.

On the upper side of FIG. 10, a driver circuit 34 that has both the function as the source driver 25 (source signal line driving function) and the function as the sensor read out driver 27 (sensor read out function) shown in FIG. 9 is provided.

In the driver circuit 34, a shift register 34a, a sensor read out/source signal line driver circuit 34b, and a switch 34c for switching between the source signal line driver function and the sensor read out function are provided. The source signal line SLr (power supply line 29) and the source signal line SLg (output signal line 30) are connected to the sensor read out/source signal line driver circuit 34b through the switch 34c.

In the above-mentioned configuration, writing into the pixel TFTs 20 and reading out of the optical sensing data obtained by the PIN diode 21 can be performed using the combined source signal line SLr (power supply line 29) and the combined source signal line SLg (output signal line 30).

Thus, this is a configuration in which reading out of the optical sensing data is performed during a blanking period during which writing into the pixel TFTs 20 is not performed.

Thus, in the above-mentioned configuration, an increase in the number of wiring lines can be significantly reduced. As a result, the active matrix substrate 1 having a high aperture ratio can be achieved.

Here, in FIG. 10, the gate driver 26 and the sensor row driver 28 are omitted from the figure.

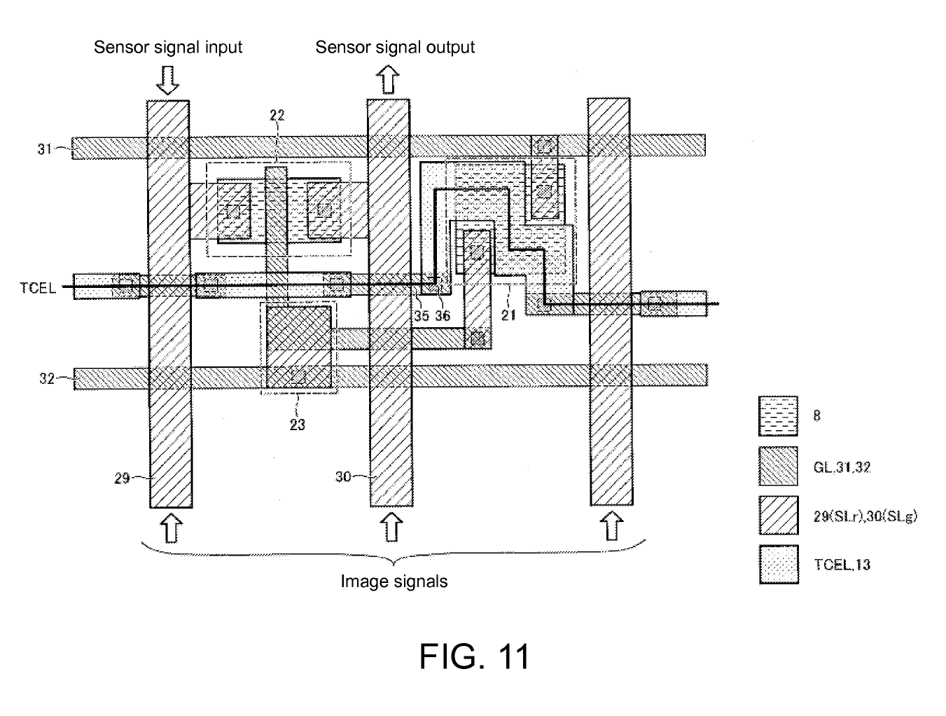

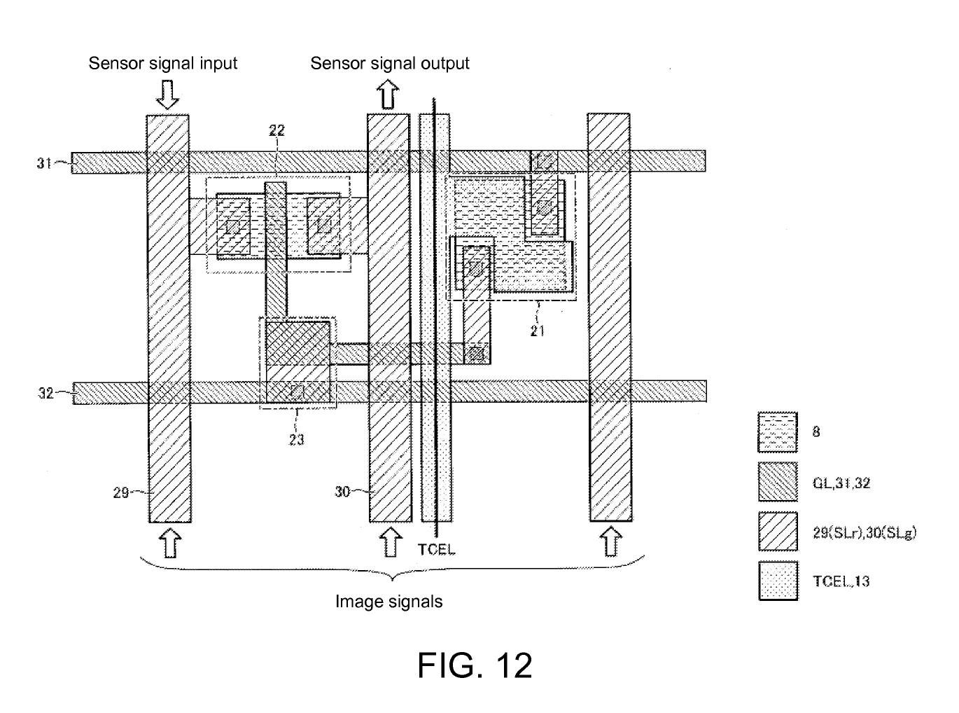

Specific wiring examples of the metal wiring network bus line TCEL are described below with reference to FIG. 11 to 12.

In the configuration of FIG. 3(a), the metal wiring network 13 is formed in a layer of the same level as the metal electrodes 12c and 12d. As a result, the arrangement of the metal wiring network bus line TCEL needs to be determined such that it does not cross the metal electrodes 12c and 12d.

FIG. 11 shows one example of the circuit configuration of FIG. 10 in which the metal wiring network bus line TCEL is led out in the extending direction of the reset signal line 31 and the row selection signal line 32.

FIG. 12 shows one example of the circuit configuration of FIG. 10 in which the metal wiring network bus line TCEL is led out in the extending direction of the combined source signal line SLr (power supply line 29) and the combined source signal line SLg (output signal line 30).

Here, although not shown in FIGS. 11 and 12, in a portion of the metal wiring network bus line TCEL located above the PIN diode 21 (this portion becomes the metal wiring network 13), openings 13b shown in FIG. 2(a) to FIG. 2(f) are formed.

In the configuration shown in FIG. 11, in order to prevent the metal wiring network bus line TCEL from crossing the combined source signal line SLr (power supply line 29) and the combined source signal line SLg (output signal line 30), which are formed in a layer of the same level as the TCLE, in a layer of the same level, a connection wiring portion 35 is formed in the intersection region below the respective signal lines, i.e., in a layer of the same level as the gate signal line GL, and is connected to the metal wiring network bus line TCEL through contact holes 36.

By using the above-mentioned configuration, the metal wiring network bus line TCEL does not cross the combined source signal line SLr (power supply line 29) and the combined source signal line SLg (output signal line 30) in a layer of the same level, and can be led out in the extending direction of the reset signal line 31 and the row selection signal line 32.

In the configuration shown in FIG. 12, in order to prevent the metal wiring network bus line TCEL from crossing the source signal line SLr (power supply line 29) and the source signal line SLg (output signal line 30), the metal wiring network bus line TCEL is formed parallel to the respective signal lines.

Thus, the metal wiring network bus line TCEL can be led out in the extending direction of the source signal line SLr (power supply line 29) and the source signal line SLg (output signal line 30) without crossing the combined source signal line SLr (power supply line 29) or the combined source signal line SLg (output signal line 30) in a layer of the same level as those signal lines.

Needless to say, the above-mentioned wiring examples can also be applied to the configuration shown in FIG. 9.

In the configuration of FIG. 14, which is described later, the metal electrodes 12c and 12d and the metal wiring network bus line TCEL are electrically insulated from each another even when they cross each other. As a result, the metal wiring network bus line TCEL can be wired in a simpler manner.

By connecting the metal wiring network 13 to either the metal electrode 12c or the metal electrode 12d (below, a case in which the metal wiring network 13 is connected to the metal electrode 12c is described), voltages can be applied to the metal wiring network 13 from the metal electrode 12c connected to the metal wiring network 13.

In the above-mentioned configuration, only the same voltage as that of the metal electrode 12c connected to the metal wiring network 13 can be applied to the metal wiring network 13. Even with this configuration, the function of suppressing influences of the electric charges can be obtained.

Furthermore, in the above-mentioned configuration, there is no need to separately provide the metal wiring network bus line TCEL. When forming the metal wiring network 13 and the metal electrodes 12c and 12d of the same conductive film, it is sufficient to simply pattern the conductive film such that the metal wiring network 13 and the metal electrode 12c are partially connected to each other. Therefore, the manufacturing process can be simplified in the above-mentioned configuration.

In the present embodiment, the respective drivers 25, 26, 27, and 28 can be monolithically formed on the active matrix substrate 1 using the polycrystalline semiconductor film 8, which has a relatively high electron mobility.

The highly reliable liquid crystal display device 19 that has a bright display quality and that has a touch panel (area sensor) function can be achieved by forming the liquid crystal display device 19 using the active matrix substrate 1 having the configuration described above.

### Embodiment 2

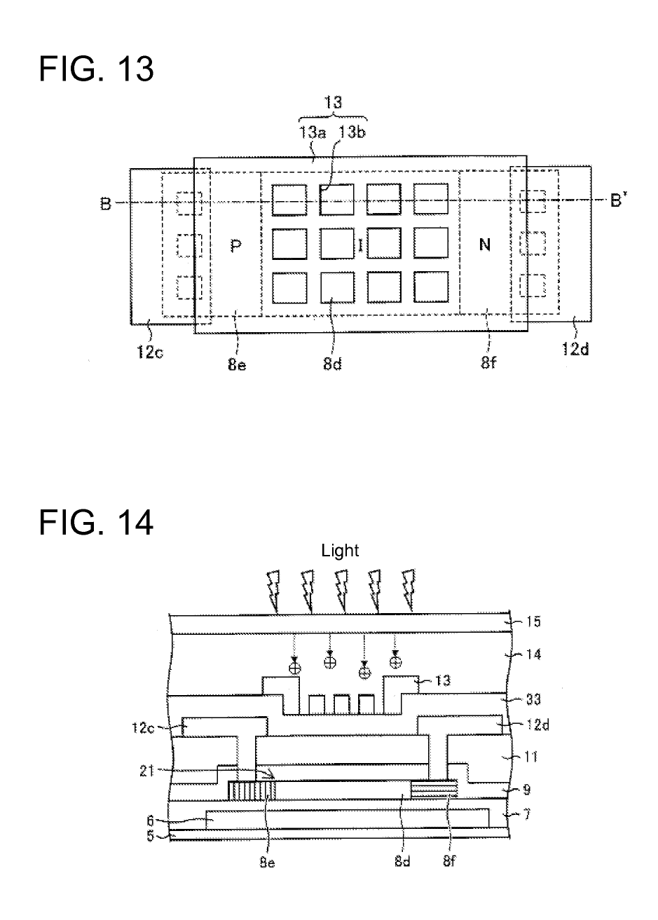

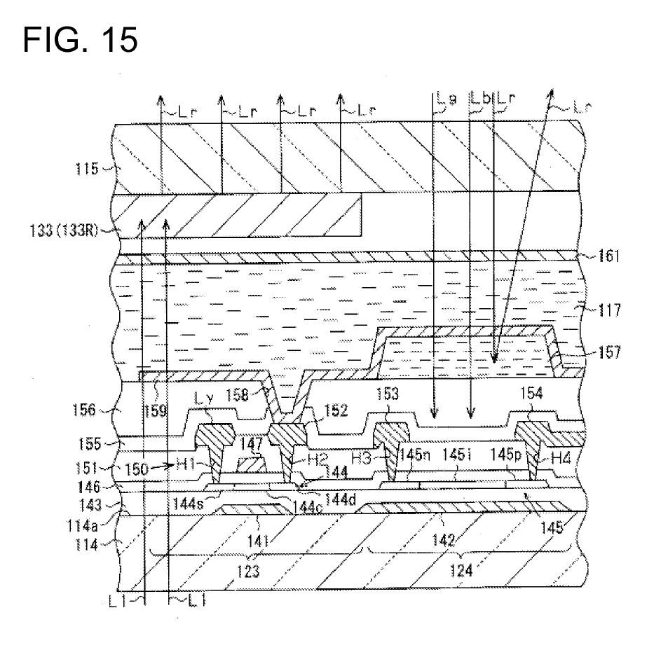

Next, Embodiment 2 of the present invention is described with reference to FIG. 13 to 14. The present embodiment is different from Embodiment 1 in that a second inorganic insulating film 33 is provided between a metal wiring network 13 and metal electrodes 12c and 12d that are connected to a PIN diode 21 through a first inorganic insulating film 11. The rest of the configuration is same as described in Embodiment 1. To facilitate the description, the same reference characters are given to the members having the same functions as the members shown in figures of Embodiment 1, and their description is omitted.

FIG. 13 is a plan view of the PIN diode 21 equipped in a substrate for display panel according to the present embodiment viewed from the side of a surface on which the metal wiring network 13 is formed.

FIG. 14 is a cross-sectional view along the line B-B′ of FIG. 13, and shows a schematic configuration of a region of the substrate for display panel of the present embodiment where the PIN diode 21 is formed.

As shown in FIGS. 13 and 14, the second inorganic insulating film 33 is disposed between the metal wiring network 13 and the metal electrodes 12c and 12d, which are connected to the PIN diode 21. As a result, the metal wiring network 13 can partially overlap the metal electrodes 12c and 12d as shown in FIG. 13.

Therefore, a short circuit caused by an alignment error between the metal wiring network 13 and the metal electrodes 12c and 12d or the like can be prevented more securely, and a substrate for display panel having even more improved reliability can be achieved.

Furthermore, even when the metal electrodes 12c and 12d and a metal wiring network bus line TCEL (see FIGS. 9 and 10) intersect, electric insulation between the metal electrodes 12c and 12d and the metal wiring network bus line TCEL is sustained because the second inorganic insulating film 33 is interposed therebetween as described above. As a result, it becomes possible to arrange the metal wiring network bus line TCEL such that it intersects with the metal electrodes 12c and 12d, and wiring of the metal wiring network bus line TCEL becomes simple.

Here, the description of the second inorganic insulating film 33 is omitted because it can be formed in a manner similar to that for the first inorganic insulating film 11.

Here, the first inorganic insulating film 11 and the second inorganic insulating film 33 may be formed of the same material.

As described above, a substrate for display panel (active matrix substrate 1) of the present invention is a substrate for display panel having a plurality of pixels, including, in a pixel: a light receiving element (PIN diode 21) that conducts currents of different values based on an amount of light received; an inorganic insulating film (first inorganic insulating film 11) formed over the light receiving element; wiring lines (metal electrodes 12c and 12d) that are formed on the inorganic insulating film and that are connected to the light receiving element; an organic insulating film (transparent organic insulating film 14) formed over the wiring; a transparent pixel electrode (transparent pixel electrode 15) formed on the organic insulating film; and a conductive film (metal wiring network 13) that is interposed between the organic insulating film and the inorganic insulating film and that is patterned so as to partially overlap and partially form an opening with respect to a light receiving section of the light receiving element.

In another aspect, a substrate for display panel (active matrix substrate 1) of the present invention includes the following: a light receiving element (PIN diode 21) that conducts currents of different values based on an amount of light received; an organic insulating film (transparent organic insulating film 14) formed on a light entrance path with respect to the light receiving element; and a conductive film (metal wiring network 13) that is formed on the entrance path so as to be interposed on a side closer to the light receiving element than the organic insulating film and that is patterned so as to partially overlap and partially form an opening with respect to a light receiving section of the light receiving element.

Furthermore, focusing on the function of the above-mentioned transparent electrode, in the present invention, it is sufficient to form a layer that at least partially forms a conductive portion and that at least partially retains the entrance path in a region of the entrance path on a side closer to the light receiving element than the organic insulating film.

The present invention is not limited to the respective embodiments mentioned above, and can be modified in various ways within the scope shown in claims. Embodiments obtained by appropriately combining technical means that are respectively described in different embodiments are included in the technical scope of the present invention.

In a substrate for display panel of the present invention, the conductive film preferably is patterned to form a grid pattern.

In the above-mentioned configuration, the overlapping portion and the openings of the conductive film are arranged to spread out. Therefore, the light guiding function and the electric charge effect suppressing function can be achieved more evenly with respect to the entire region of the light receiving section of the light emitting element.

The substrate for display panel of the present invention preferably further includes a bus line that is electrically connected to the conductive film and that extends outside the display region of the substrate for display panel.

In the above-mentioned configuration, a prescribed voltage can be applied to the conductive film by applying a voltage to an end of the bus line that is led out from the display region of the substrate for display panel. This way, the above-mentioned influences on the light receiving element caused by a capacitance coupling of electric charges can be suitably suppressed.

Here, conductive films that are respectively provided in a plurality of pixels are electrically connected to the bus line respectively. The bus line preferably is made such that it can supply a voltage to the plurality of conductive films at once.

Alternatively, in the substrate for display panel of the present invention, the conductive film may be connected to the wiring.

In the above-mentioned configuration, the same voltage as that of the wiring is applied to the conductive film. The influences on the light receiving element caused by a capacitance coupling of electric charges can be prevented this way as well. Furthermore, in this configuration, there is no need to provide a bus line separately. As a result, the process steps can be simplified.

In the substrate for display panel of the present invention, the light receiving element preferably is a photodiode that has a P-layer, which is a semiconductor layer having a relatively high P-type impurity concentration, an I-layer, which is either an intrinsic semiconductor layer or a semiconductor layer having a relatively low impurity concentration, and an N-layer, which is a semiconductor layer having a relatively high N-type impurity concentration. The light receiving section preferably is the I-layer.

In the substrate for display panel of the present invention, the P-layer, the I-layer, and the N-layer in the photodiode preferably are arranged in an in-plane direction.

Because the above-mentioned configuration is a configuration in which the respective layers of the P-layer, the I-layer, and the N-layer do not overlap with one another, parasitic capacitances between the respective layers are lowered, and the sensing speed as an optical sensor can be increased.

Here, the photodiode can be manufactured in a simple manner using the same manufacturing process as that of an active element, such as a TFT (Thin Film Transistor) or the like formed on the substrate for display panel.

Thus, a substrate for display panel that has a light receiving element having fast sensing speed can be manufactured in a relatively simple manner.

In the substrate for display panel of the present invention, the conductive film and the wiring preferably are formed of the same material.

In the above-mentioned configuration, the conductive film and the wiring are formed of the same material. As a result, they can be formed by patterning the same film.

The substrate for display panel of the present invention preferably further includes a second inorganic insulating film interposed between the conductive film and the wiring.

In the above-mentioned configuration, a short circuit caused by an alignment error between the conductive film and the wiring or the like can be prevented more securely, and a substrate for display panel having even more improved reliability can be achieved.

In the substrate for display panel of the present invention, the first inorganic insulating film and the second inorganic insulating film may be formed of the same material.

In order to solve the above-mentioned problems, the substrate for display panel of the present invention is characterized in that it has a light receiving element that conducts currents of different values based on the amount of light received, an organic insulating film formed on a light entrance path with respect to the light receiving element, and a conductive film that is formed on the entrance path so as to be interposed on a side closer to the light receiving element than the organic insulating film and that is patterned so as to partially overlap and partially form an opening with respect to a light receiving section of the light receiving element.

In the above-mentioned configuration, the conductive film is formed on the entrance path so as to be interposed on a side closer to the light receiving element than the organic insulating film. Therefore, even when electric charges are stored in the organic insulating film, influences of these electric charges upon the light receiving element due to a capacitance coupling can be suppressed.

The conductive film is formed on the light entrance path. However, the conductive film can guide light towards the light receiving element side because it partially forms an opening.

Thus, even when a configuration using an organic insulating film is used and the light receiving element is driven for a long time, a substrate for display panel having a light receiving element that can suppress degradation of photocurrent characteristics of the light receiving element and that has improved reliability can be achieved.

In order to solve the above-mentioned problems, a display device according to the present invention is characterized in that it is provided with the above-mentioned substrate for display panel.

In the above-mentioned configuration, the display device has the substrate for display panel having a light receiving element. Therefore, a highly reliable display device that has a bright display quality and that has a touch panel (area sensor) function can be achieved.

### INDUSTRIAL APPLICABILITY

The present invention can be applied to display devices, which are represented by liquid crystal display devices and organic EL display devices.

### DESCRIPTION OF REFERENCE CHARACTERS

1 active matrix substrate (substrate for display panel)
8 polycrystalline semiconductor film
8d Mayer of PIN diode (light receiving section of light receiving element)
8e P-layer of PIN diode (semiconductor layer of light receiving element)
8f N-layer of PIN diode (semiconductor layer of light receiving element)
11 first inorganic insulating film
12c, 12d metal electrodes (wiring lines)
13 metal wiring network (conductive film)
14 organic insulating film
15 transparent pixel electrode
19 liquid crystal display device (display device)
21 PIN diode (light receiving element)
33 second inorganic insulating film

1. A substrate for display panel having a plurality of pixels, comprising, in a pixel:
a light receiving element that conducts currents of different values based on an amount of light received;
a first inorganic insulating film formed over said light receiving element;
a wiring that is formed on said first inorganic insulating film and that is electrically connected to said light receiving element;
an organic insulating film formed over said wiring;
a transparent pixel electrode formed on said organic insulating film; and
a conductive film that is interposed between said organic insulating film and said first inorganic insulating film and that is patterned so as to partially overlap and partially form an opening with respect to a light receiving section of said light receiving element.

2. The substrate for display panel according to claim 1, wherein said conductive film has a grid pattern.

3. The substrate for display panel according to claim 1, further comprising a bus line that is electrically connected to said conductive film and that extends outside a display region of said substrate for display panel.

4. The substrate for display panel according to claim 1, wherein said conductive film is connected to said wiring.

5. The substrate for display panel according to claim 1, wherein said light receiving element is a photodiode having a P-layer that is a semiconductor layer having a relatively high P-type impurity concentration, an Mayer that is either an intrinsic semiconductor layer or a semiconductor layer having a relatively low impurity concentration, and an N-layer that is a semiconductor layer having a relatively high N-type impurity concentration, and
wherein said light receiving section is said Mayer.

6. The substrate for display panel according to claim 5, wherein said P-layer, said I-layer, and said N-layer in said photodiode are arranged in an in-plane direction.

7. The substrate for display panel according to claim 1, wherein said conductive film and said wiring are formed of a same material.

8. The substrate for display panel according to claim 1, further comprising a second inorganic insulating film interposed between said conductive film and said wiring.

9. The substrate for display panel according to claim 8, wherein said first inorganic insulating film and said second inorganic insulating film are formed of a same material.

10. A substrate for display panel, comprising:
a light receiving element that conducts currents of different values based on an amount of light received;
an organic insulating film formed on a light entrance path with respect to said light receiving element; and
a conductive film that is formed on said entrance path so as to be interposed on a side closer to said light receiving element than said organic insulating film and that is patterned so as to partially overlap and partially form an opening with respect to a light receiving section of said light receiving element.

11. A display device, comprising the substrate for display panel according to claim 1.
